(19) United States
(12) Patent Application Publication
(10) Pub. No.: US 2005/0208433 A1
(43) Pub. Date: Sep. 22, 2005

(54) Pattern forming method, circuit substrate and electronic apparatus

(75) Inventors: Kazuaki Sakurada, Suwa-shi (JP); Tsuyoshi Shintate, Matsuyama-machi (JP); Toyotaro Kinoshita, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/078,380

(22) Filed: Mar. 14, 2005

(30) Foreign Application Priority Data
Mar. 22, 2004 (JP) 2004-082424

(51) Int. Cl. G03F 7/00

(52) U.S. Cl. 430/322; 430/935

(57) ABSTRACT

A pattern forming method includes the step of forming a partition wall, at least a portion of a boundary betweeen a pattern formation area and other areas, by coating droplets usng a droplet discharge method.

### BACKGROUND OF THE INVENTION

1. Field of the Invention

The present invention relates to a pattern forming method, a circuit substrate, and an electronic apparatus.

Priority is claimed on Japanese Patent Application No. 2004-82424, filed Mar. 22, 2004, the contents of which are incorporated herein by reference.

2. Description of Related Art

A lithographic method, for example, can be used to manufacture wires or insulating films or the like that are used in electronic circuits or integrated circuits or the like. A lithographic method requires large-scale equipment such as a vacuum apparatus and the like, as well as complicated processing. Moreover, the material utilization efficiency of a lithographic method is only a very low and a large majority of the material ends up as waste. Consequently, manufacturing costs are high. Because of this, a method in which a liquid that contains a functional material is directly patterned onto a substrate by inkjets (i.e., a droplet discharge method) is being investigated as a method that can be employed instead of a lithographic method. For example, a method has been proposed (see, for example, U.S. Pat. No. 5,132,248) in which a liquid, in which fine conductive particles have been dispersed, is directly coated in a pattern onto a substrate using a droplet discharge method. Heat processing and laser radiation are then carried out so that the liquid is converted into a conductive film pattern.

Furthermore, conventionally, a method of forming multilayer wiring has been proposed (see, for example, Japanese Unexamined Patent Application, First Publication (JP-A) No. 2003-318542) that makes it possible to form a multilayer wiring substrate having a high wiring density comparatively easily using a droplet discharge method.

However, in the pattern forming method described in U.S. Pat. No. 5,132,248 and in the multilayer wiring formation method described in JP-A No. 2003-318542, it is difficult to form narrow diameter through holes in a flat, substantially uniform thin film pattern formation area. Namely, in order to form a flat, substantially uniform thin film pattern formation area, it is necessary to coat a liquid material onto the thin film pattern formation area. Firstly, a small diameter hole to be used for a through hole is formed in the thin film pattern formation area. Next, when the liquid material is coated on the thin film pattern formation area, the liquid material flows into this hole so that the hole becomes blocked by the liquid material. As a result, conventionally, it is not possible to easily form a through hole in a flat, substantially uniform thin film pattern.

Moreover, if there are corners in the flat, substantially uniform thin film pattern formation area, it is difficut for the liquid material to penetrate into the corners even if the liquid material is coated inside the thin film pattern formation area. As a result, conventionally, it has not been possible to easily form a flat, substantially uniform thin film pattern that has small-sized corners.

The present invention was conceived in view of the above described circumstances, and it is an object thereof to provide a pattern forming method that makes it possible to easily form a thin film pattern having the desired configuration using a droplet discharge method, and to a circuit substrate and an electronic apparatus.

In addition, it is an object of the present invention to provide a pattern forming method that makes it possible to form a flat, substantially uniform thin film pattern easily and with a high degree of accuracy using a droplet discharge method, and to a circuit substrate and an electronic apparatus.

In addiion, it is an object of the present invention to provide a pattern forming method that makes it possible to form a through hole in a flat, substantially uniform thin film pattern easily and with a high degree of accuracy using a droplet discharge method, and to a circuit substrate and an electronic apparatus.

### SUMMARY OF THE INVENTION

In order to achieve the above objects, the pattern forming method of the present invention has the step of forming a partition wall, at least a portion of a boundary between a pattern formation area and other areas, by coating droplets using a droplet discharge method.

According to the present invention, a partition wall is provided using a droplet discharge method that discharges a liquid material in the form of droplets. Accordingly, it is possible, for example, for this partition wall to form an embankment, and for the parition wall to prevent liquid material that has been coated in the pattern formation area from escaping outside this area. Therefore, according to the present invention, a thin film pattern that uses a liquid material or the like can be formed in an extremely precise configuration. In addition, according to the present invention, because an embankment having an optional configuration can be formed accurately and at low cost using a droplet discharge method, an extremely precise thin film pattern can be formed at low cost.

In the pattern forming method of the present invention, it is preferable that the partition wall is formed in a linear configuration by performing at least a first coating in which a plurality of droplets are coated onto at least a portion of the boundary with a space between each droplet using a droplet discharge method, and a second coating in which, after the first coating, droplets are coated onto the spaces using the droplet discharge method. Here, it is also possible after the completion of the second coating to perform a third coating and a fourth coating and the like that further coat droplets between each of the droplets.

According to the present invention, is possible to easily form a desired linear partition wall in the form of a straight line or curved line without using a mask or the like in a photolithographic method.

In the pattern forming method of the present invention, it is preferable that the second coating is performed after at least a surface of a thin film formed by the droplets coated in the first coating has hardened. Moreover, in the pattern forming method of the present invention, it is preferable that the thin film formed by the droplets coated in the first coating and the thin film formed by the droplets coated in the second coating have overlapping portions.

According to the present invention, when a portion of the droplets of the first coating and a portion of the droplets of the second coating overlap, it is possible to avoid a situation in which the droplets of the second coating are pulled towards the droplets of the first coating resulting in the coating positions being displaced. Consequently, a thin film can be formed with an extremely accurate configuration. Moreover, according to the present invention, the thin film created by the droplets of the second coating can be formed on a top layer of the thin film created by the droplets of the first coating, so that the film thickness can be easily increased, and the height of the partition wall can be easily increased.

Moreover, in the pattern forming method of the present invention, it is preferable that a flat, substantially uniform thin film is formed in the pattern formation area. Moreover, in the pattern forming method of the present invention, it is preferable that the flat, substantially uniform thin film is formed after at least surfaces of the droplets that constitute the partition wall have hardened.

According to the present invention, even if, for example, the interior of the pattern formation area is filled with a comparatively large quantity of liquid material, this large quantity of liquid material can be prevented by the partition wall from flowing out from the pattern formation area. Therefore, according to the present invention, a flat, substantially uniform thin film pattern can be formed in an extremely accurate configuration and at low cost.

Moreover, in the pattern forming method of the present invention, it is preferable that the boundary is a boundary region between a through hole provided in a pattern formation surface that includes the pattern formation area, and the pattern formation surface.

According to the present invention, when, for example, forming a through hole that penetrates the flat, substantially uniform thin film pattern, by providing the partion wall it is possible to avoid a situation in which the liquid material used to form the thin film pattern flows into the through hole and fills up the through hole. Therefore, according to the present invention, it is possible to easily and accurately form a desired thin film pattern and a through hole that penetrates this thin film pattern. Therefore, according to the present invention, a precise, multilayer substrate and the like can be manufactured accurately and at low cost.

Moreover, in the pattern forming method of the present invention, it is preferable that the pattern formation area has corner portions, and that at least a portion of the bondary is the corner portion.

According to the present invention, because partition walls are located in the corner portions, by filling the interior of the pattern formation area with the liquid material, the liquid material can be made to penetrate easily as far as the vertices of these corner portions. In contrast, if partition walls are not provided at corner portion boundaries, it is difficult to make the liquid material that fills the interior of the pattern formation area penetrate as far as the vertices of the corner portions. According to the present invention, corner portions of a thin film pattern can be manufactured accurately and at low cost. =p Moreover, in the pattern forming method of the present invention, it is preferable that, prior to the partition wall being provided, liquid-repellency imparting process or liquid-affinity imparting process is performed on an area that includes a location where the partition wall is provided.

According to the present invention, by performing liquid-repellency imparting process or liquid-affinity imparting process on a location where a partition wall is to be provided and/or on the periphery thereof, the partition wall can be formed with a high degree of accuracy. Therefore, according to the present invention, it is possible to form a more accurate thin film pattern.

Moreover, in the pattern forming method of the present invention, it is preferable that, prior to the partition wall being provided, liquid-repellency imparting process is performed on a location where the partition wall is provided and on areas adjacent to this location.

According to the present invention, it is possible to restrict droplets that have been dropped onto a location where a partition wall is to be provided from spreading out. Therefore, the present invention is able to form an extremely accurate partition wall at low cast using a droplet discharge method.

Moreover, in the pattern forming method of the present invention, it is preferable that, prior to a flat, substantilly uniform thin film being formed on the pattern formation area, liquid-affinity imparting process or liquid-repellency imparting process is performed on the pattern formation area.

According to the present invention, because the lyophilicity or repellency of the pattern formation area is controlled, a more accurate thin film pattern can be formed in the pattern formation area.

Moreover, in the pattern forming method of the present invention, it is preferable that, prior to a flat, substantially uniform thin film being formed on the pattern formation area, liquid-affinity imparting process is performed on areas other than the vicinty of the boundary in the pattern formation area.

According to the present invention, the liquid material spreads easily to areas other than the vicinity of the boundary inside the pattern formation area, so that the spread of liquid material to the boundary vicinity can be controlled. Therefore, the present invention enables the height of the partition wall to be lowered, and enables a more accurate thin film pattern to be formed in the pattern formation area.

Moreover, in the pattern forming method of the present invention, it is preferable that the pattern formation area is provided on a reel-to-reel substrate that is formed by a tape-shaped substrate, with both end portions of the tape-shaped substrate each being wound up.

According to the present invention, an extremely accurat thin film pattern can be formed on a reel-to-reel substrate using a droplet discharge method. Accordingly, the present invention enables a substrate provided with an extremely accurate thin film pattern to be manufactured in quantity and at an even lower cost.

In order to achieve the above described objects, the circuit substrate of the present invention is a circuit substrate having a pattern that has been formed using the above described pattern forming method.

According to the present invention, a circuit substrate having an electronic circuit or the like that is formed by a pattern which has been manufactured extremely accurately can be provided at a low cost. Accordingly, it is possible, for example, to provide an electronic circuit substrate that is more densely integrated than is the case conventionally. In addition, the present invention enables a circuit substrate having fine, multilayer substrate to be provided with a high degree of accuracy and at low cost.

In order to achieve the above described objects, the electronic apparatus of the present invention is an electronic apparatus that has been manufactured using the above described pattrn forming method.

According to the present invention, an electronic apparatus that is provided with a substrate that has wiring or electronic circuits made up of thin film patterns can be manufactured at low cost.

### BRIEF DESCRIPTION THE DRAWINGS

FIG. 1A to 1D are typical plan views showing a pattern forming method according to the first embodiment of the present invention.

FIG. 2 is a cross-sectional view taken at a position XX′ in FIG. 1D.

FIG. 3 is a view showing the entire substrate of FIG. 1D.

FIGS. 4A and 4B are plan views showing a variant example of the first embodiment.

FIG. 5 is a typical plan view showing a pattern forming method according to the second embodiment of the present invention.

FIG. 6 is a perspective view showing an example of a droplet discharge apparatus that is used in the embodiments of the present invention.

FIGS. 7A and 7B are views showing an inkjet heead of the above droplet discharge apparatus.

FIG. 8 is a bottom view of the above inkjet head.

FIG. 9 is a typical view showing an outline of a method of manufacturing a multilayer wiring substrate according to the present embodiment.

FIG. 10A to 10C are perspective views showing electronic apparatuses according to the embodiments of the present invention.

### DETAILED DESCRIPTION OF THE INVENTION

The pattern forming method acccording to embodiments of the present invention will not be described below with reference made to the drawings.

### First Embodiment

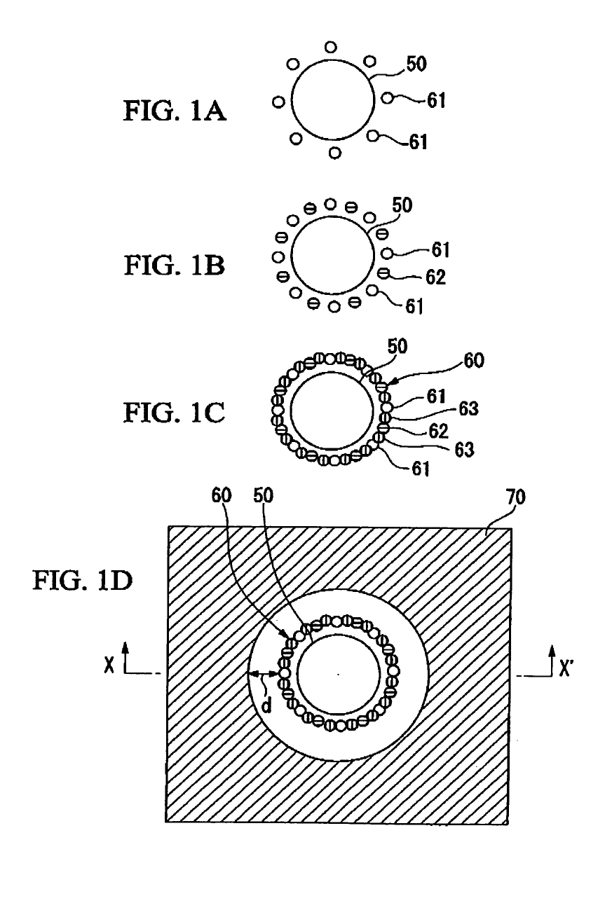

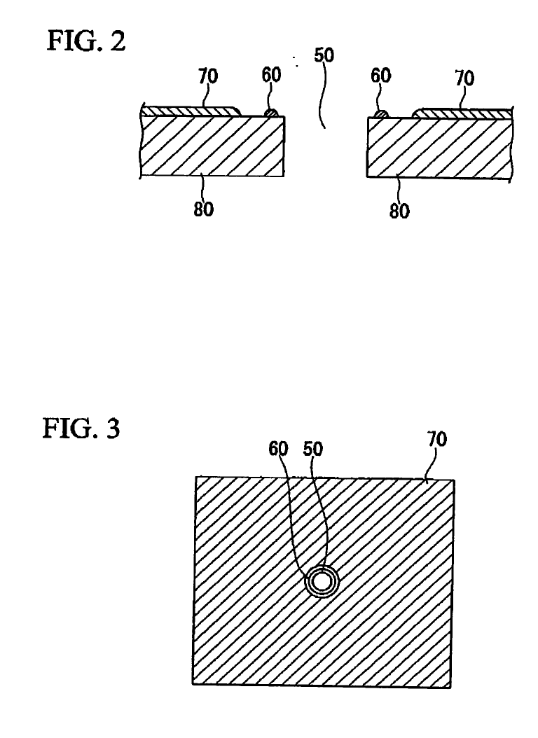

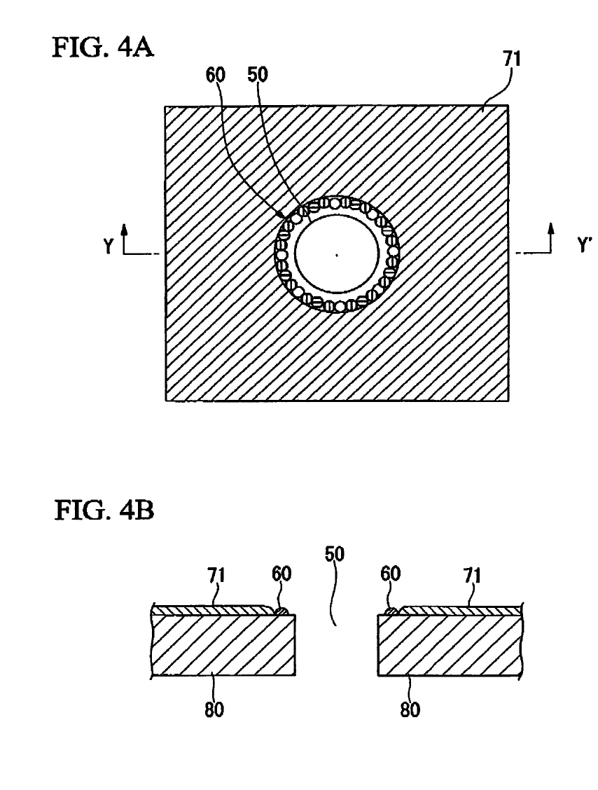

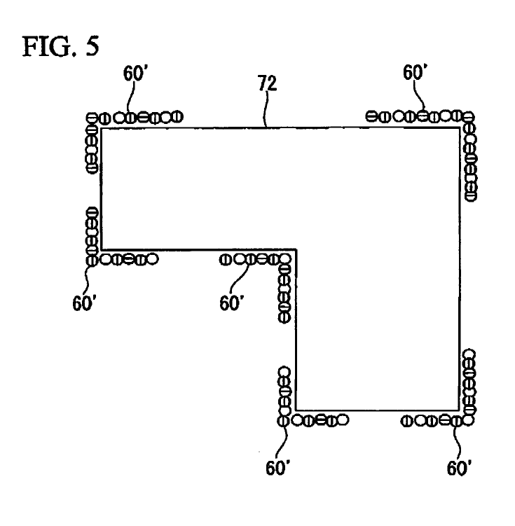

FIG. 1A to 1D are typical plan views showing a pattern forming method according to the first embodiment of the present invention. FIG. 2 is a cross-sectional view taken at a position XX′ in FIG. 1D. FIG. 3 is a view showing the entire substrate of FIG. 1D. A substrate 80 in the present embodiment is an example of a circuit substrate according to the present invention. In the present embodiment, a description is give of an example in which a flat, substantially uniform thin film 70 is provided over one entire surface of the substrate 80, and a through hole is provided so as to penetrate the thin film 70.

Firstly, as is shown in FIG. 1, a hole 50, which will ultimately become a through hole, is formed in a pattern formation area on the substrate 80. This pattern formation area is the entire area over which a flat, substantially uniform thin film will be formed in later steps. Next, the periphery of the hole 50 in the pattern formation area is coated by a plurality of droplets 61 that are dropped thereon at a uniform spacing (a first coating). A droplet discharge method in which a liquid material is discharged in the form of droplets from an inkjet nozzle of a droplet discharge apparatus is used for the coating by the droplets 61.

Next, as is shown in FIG. 1B, gaps between each of the droplets 61 on the substrate 80 are coated with droplets 62 using a droplet discharge method (a second coating).

Next, as is shown in FIG. 1C, gaps between each of the droplets 61 and the droplets 63 on the substrate 80 are coated with droplets 63 using a droplet discharge method (a third coating). The droplets 61, 62, and 63 are then cured. As a result, a ring-shaped partition wall 60 is formed around the hole 50 on the substrate 80. In other words, the partition wall 60 is formed at the boundary between the pattern formation area and other areas (i.e., the hole 50) on the substrate 80.

Next, as is shown in FIG. 1D and in FIG. 2, the flat, substantially uniform think film 70 is formed over the entire pattern formation area on the substrate 80. It is preferable that a uniform spacing d is formed between the thin film 70 and the partition wall 60.

As a result of the above, according to the present embodiment, it is possible to provide the partition wall 60 using a droplet discharge method. Accordingly, the partition wall 60 forms an embankment, and it is possible to prevent the liquid material that has been coated onto the pattern formation area from intruding into the hole 50 from this area. Therefore, according to the present embodiment, when a through hole is placed in a pattern formation area where a flat, substantially uniform thin film is to be created, it is possible to prevent this through hole from becoming filled up with the liquid material that is used to form the flat, substantially uniform thin film.

Moreover, for example, by using the flat, substantially uniform thin film 70 as an insultating layer, and by creating the through hole from the hole 50, and then stacking a plurality of the substrates 80 shown in FIG. 2 and the like on top of each other, it is possible to form a multilayer substrate (one of the circuit substrates according to the present invention). As a result, according to the present embodiment, it is possible to provide a circuit substrate having precise multilayer substrates at a low cast and with a high degree of accuracy.

Moreover, in the present embodiment, it is preferable that the droplets 61 and/or the droplets 63 and droplets 63 have overlapping portions. If this structure is employed, it is possible to form a partition wall 60 that can form an embankment without any gaps in it. If overlapping portions are provided in this manner, it is preferable that the coating of the droplets 63 in the third coating is performed after at least the surfaces of the droplets 61 and 62 that have been used for the first coating and second coating have cured. If this method is employed, it is possible to prevent the droplets 63 of the third coating from being drawn towards droplets 61 and 62 of the first and second coatings that have not yet cured and causing a displacement of the coating positions or the like. As a result, it is possible to form a thin film that has a precise shape. It is also possible to form the thin film that is created by the droplets 63 of the third coating on the top layer of the thin film that is created by the droplets 61 and 62 of the first and second coatings, thereby enabling the film thickness to be easily increased, and enabling the height of the partition wall 60 to be easily increased. Note that the height of the partition wall 60 can be increased by providing a thin film that is created by a fourth and subsequent coatings on the top layer of the thin film that is created from the first through third coatings.

Moreover, in the present embodiment, before the partion wall 60 is formed, namely, before the droplets 61 are dropped, it is also possible to peerform liquid-repellency imparting process or liquid-affinity imparting process on an area that includes the location where the partition wall 60 is to be formed. Namely, liquid-repellency imparting process or liquid-affinity imparting process is performed on the periphery of the hole 50 in the substrate 80.

If, for example, liquid-repellency imparting process is performed on the periphery of the hole 50 prior to the dropping of the droplets 61, then it is possible to prevent the droplets 61, 62, and 63 that have been dropped onto the position where the partition wall 60 is being formed from spreading out. Accordingly, the partition wall 60 can be formed with a high degree of accuracy using the droplet discharge method.

Moreover, in the present embodiment, before the flat, substantially uniform thin film 70 is formed on the pattern formation area, it is preferable that liquid-repellency imparting process or liquid-affinity imparting process is performed on this pattern formation area. If, for example, prior to the thin film 70 being formed on the pattern formation area, liquid-affinity imparting process is performed in areas other than the vicinity of the hole 50 in this pattern formation area, then the liquid material spreads excellently over the entire pattern formation area, and the thin film is able to be formed as an extremely uniform, flat, substantially uniform thin film 70. Accordingly, the present embodiment enables a thin film pattern to be formed more accurately while enabling the height of the partition wall 60 to be reduced.

FIGS. 4A and 4B are plan views showing a variant example of the present embodiment. In the variant example shown in FIGS. 4A and 4B, an arrangement is employed in which no gap is provided between a thin film 71 that corresponds to the thin film 70 shown in FIG. 1A to 1D and the partition wall 60. Namely, the flat, substantially uniform thin film 71 is formed so as to extend to a side surface of the partition wall 60. The remainder of the structure is the same as in the pattern forming method shown in FIG. 1A through FIG. 3.

### Second Embodiment

FIG. 5 is a typical plan view showing a pattern forming method according to the second embodiment of the present invention. In the present embodiment, the pattern formation area has corner portions, and partition walls 60′ are provided along an outer edge of these corner portions. The partition walls 60′ correspond to the partition wall 60 of the first embodiment and the method of manufacturing the partion walls 60′ is the same as that used to manufacture the partion wall 60.

According to the present embodiment, because the partition walls 60′ are placed at corner portions of the pattern formation area, by filling the interior of the pattern formation area with the liquid material, the liquid material is able to penetrate easily as far as the vertices of these corner portions. Accordingly, according to the present embodiment, it is possible to manufacture flat, substantially uniform thin films 72 that have corner portions at low cost and with a high degree of precision.

(Droplet Discharge Apparatus)

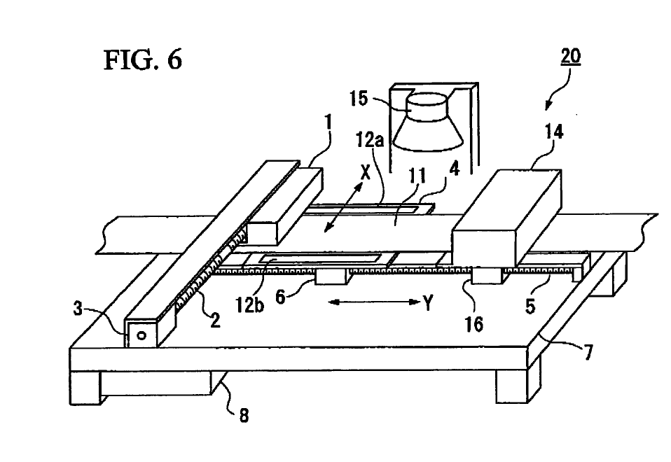

FIG. 6 is a perspective view showing an example of the droplet discharge apparatus that is used in the pattern forming method of the above described embodiments. A droplet discharge apparatus 20 of this example discharges droplets onto a tape-shaped substrate 11. The tape-shaped substrate 11 is an example of the substrate 80 of the above described embodiments, and is a reel-to-reel substrate in which the two end portions of the tape can be be wound up.

The droplet discharge apparatus 20 is provided with an inkjet head group (i.e., a discharge head) 1, an X direction guide shaft (i.e. guide) 2 that drives the ink jet head group 1 in the X direction, and an X direction drive motor 3 that rotates the X direction guide shaft 2. In addition, the droplet discharge apparatus 20 is provided with a mounting base 4 on which the tape-shaped substrate 11 is mounted, a Y direction guide shaft 5 that is ued to drive the mounting base 4 in a Y direction, and a Y direction drive motor 6 that rotates the Y direction guide shaft 5. The droplet disharge apparatus 20 is also provided with a base 7, and the X direction guide shaft 2 and the Y direction guide shaft 5 are both fixed to predetermined positions on the base 7. A control unit 8 is provided underneath the base 7. The droplet discharge apparatus 20 is also provided with a cleaning mechanism section 14 and a heater 15.

Here, the X direction guide shaft 2, the X direction drive motor 3, the Y direction guide shaft 5, the Y direction drive motor 6, and the mounting base 4 constitute a head moving mechanism that moves the inkjet head group 1 relatively to a tape-shaped substrate 11 that has been aligned on the mounting base 4. The X direction guide shaft 2 is a guide that, simultaneously with a droplet discharge operation from the inket head group 1, moves the inket head group 1 in a direction that intersects the longitudinal direction of the tape-shaped substrate 11 (i.e., the Y direction) substantilly at a right angle.

The inkjet head group 1 is provided with a plurality of inket heads that discharge, for example, a dispersion solution that contains fine conductive grains from nozzles (i.e., discharge apertures) and supply it to the tape-shaped substrate 11 at predetermined spacings. It is possible for each of this plurality of inkjet heads to individually discharge the dispersion solution in accordance with a discharge voltage that is output from the control unit 8. The inkjet head group 1 is fixed to the X direction guide shaft 2, and the X diredction drive motor 3 is connected to the X direction guide shaft 2. The X direction drive motor 3 is a stepping motor or the like. When the X direction drive motor 3 receives an X direction drive pulse signal from the control unit 8, it rotates the X direction guide shaft 2. When the X direction guide shaft 2 is rotated, the inkjet head group 1 moves in the X axial direction along the base 7.

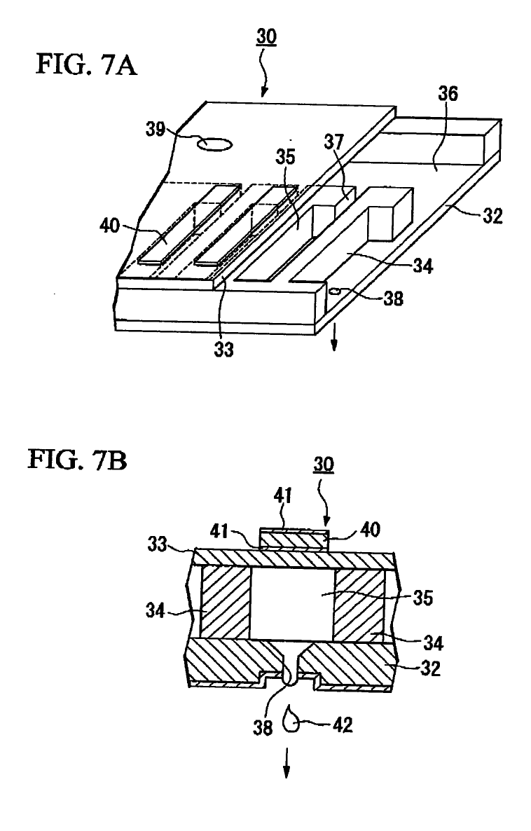

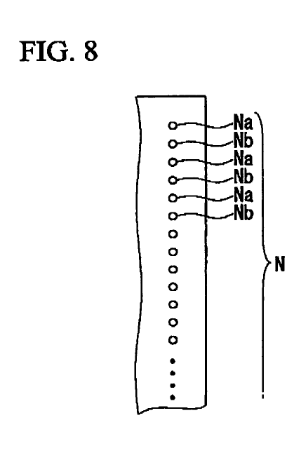

Here, the plurality of inkjet heads that make up the inket head group 1 will be described in detail. FIGS. 7A and 7B are views showing an inkjet head 30. FIG. 7A is a perspective view of the principal portions, whicle FIG. 7B is a cross-sectional view of the principal portions. FIG. 8 is a bottom v iew of the inkjet head 30.

As is shown in FIG. 7A, the inkjet head 30 is provided with a nozzle plate 32 formed from, for example, stainless steel and a diaphragm 33, and these two are joined together via a partitioning member (i.e., a reservoir plate) 34. A plurality of spaces 35 and a solution container 36 are formed by the partitioning members 34 between the nozzle plate 32 and the diaphragm 33. The interiors of each space 35 and of the solution container 36 are filled with a liquid material, and the respective spaces 35 and the solution container 36 are connected together via supply ports 37. A plurality of nozzle holes 38 that expel liquid material from the spaces 35 are formed in rows running in vertical and horizontal direction in the nozzle plate 32. A hole 39 that is used to supply the liquid material to the solution container 36 is formed in the diaphragm 33.

As is shown in FIG. 7B, a piezoelectric element 40 is joined onto the surface of the diaphragm 33 on the opposite side to the surface thereof that faces the spaces 35. The piezoelectric element 40 is positioned between a pair of electrodes 41, and a structure is employed in which, when energized, the piezoelectric element 40 flexes so as to protrude outwards. As a result of this structure, the diaphragm 33 to which the piezoelectric element 40 is joined also flexes outwards at the same time integrally with the piezoelectric element 40. Consequently, the volume of the space 35 increases. Accordingly, liquid material corresponding to the amount of the increase in the volume of the space 35 flows into the space 35 from the solution container 36 via the supply port 37. When the energizing of the piezoelectric element 40 is terminated in this state, the piezoelectric element 40 and the diaphragm 33 both return to their original configurations. Accordingly, because the space 35 is also restored to its original volume, the pressure of the liquid material inside the space 35 is raised, and droplets 42 of this liquid material are discharged from the nozzle hole 38 towards a substrate.

Note that, because an inkject head 30 that has the structure described above has a substantially rectangular bottom surface, as is shown in FIG. 8, nozzles N (i.e., the nozzle holes 3 and 8) are arranged on the rectangle so as to be positioned equidistantly in a vertical direction. In the present example, every second nozzle from among all of the nozzles of the row of nozzles that are arranged in this vertical direction, namely in the longitudinal direction, is taken as a main nozzle (i.e., a first nozzle) Na, and the nozzles positioned between these main nozzles Na are taken as sub-nozzles (i.e., second nozzles) Nb.

A piezoelectric element 40 is provided independently for each of the respective nozzles N (i.e., the nozzles Na and Nb), so that a discharge operation can be performed independently for each nozzle No. Namely, by controlling the discharge waveform in the form of the electrical signals that are sent to these piezoelectric elements 40, the quantity of the droplets that are discharged from each of the nozzles N can be regulated and changed. Here, this control of the discharge waveform is carried out by the control unit 8, and a result of this type of structure being employed, the control unit 8 is also able to function as a discharge quantity adjusting device that changes the quantity of droplets that are discharged from each of the nozzles N.

Note that the type of inkjet head 30 is not limited to a piezo-jet type that uses the piezoelectric element 40, and, for example, it is also possible to use a thermal type. In this case, by changing the application time, the quantity of droplets that are discharged can be changed.

Returning to FIG. 6, the mounting base 4 is used to mount the tape-shaped substrate 11 onto which the dispersion solution is coated by the droplets discharge pparatus 20, and is provided with a mechanism (i.e., an alignment mechanism) for fixing the tape-shaped substrate 11 in a reference position. The mounting base 4 is fixed to the Y direction guide shaft 5, and Y direction drive motors 6 and 16 are connected to the Y direction guide shaft 5. The Y direction drive motors 6 and 16 are stepping motors or the like. When the Y direction drive motors 6 and 16 receive a Y axial direction drive pulse signal from the control unit 8, they rotate the Y direction guide shaft 5. When the Y direction guide shaft 5 is rotated, the mounting base 4 moves in the Y axial direction along the base 7.

The droplets discharge apparatus 20 is provided with a cleaning mechanism section 14 that cleans the inkjet head group 1. The cleaning mechanism section 14 is able to be moved along the Y direction guide shaft 5 by the Y direction drive motor 16. The movement of the cleaning mechanism section 14 is also controlled by the control unit 8.

Next, a description of flashing areas 12a and 12b of the droplet discharge apparatus 20 will be given. Two flashing areas 12a and 12b are provided on the mounting base 4 of the droplet discharge apparatus 20. The flashing areas 12a and 12b are located on both sides in the transverse direction (i.e., in the X direction) of the tape-shaped substrate 11, and are areas into which the inkjet head group 1 is able to be moved by the X direction guide shaft 2. Namely, the flashing areas 12a and 12b are placed on both sides of a desired area which is an area that corresponds to one circuit substrate on the tape-shaped substrate 11. The flashing areas 12a and 12b are also areas where the dispersion solution lands when discharged from the inkjet head group 1. By providing the flashing areas 12a and 12b in this manner, the inkjet head group 1 is able to be moved rapidly to either the flashing area 12a or the flashing area 12b along the X direction guide shaft 2. For example, if there is a desire for the inkjet head group 1 to perform a flashing in the vicinity of the flashing area 12b, then the inkjet head group 1 can be moved to the comparatively near flashing area 12b and the flashing can be performed immediately without the inket head group 1 having to move to the comparatively distant flashing area 12a.

Here, the heater 15 is an apparatus for performing heating processing (i.e., drying processing or baking processing) on the tape-shaped substrate 11 by lamp annealing. Namely, the heater 15 vaporizes and dries liquid material that has been discharged onto the tape-shaped substrate 11, and also performs head processing in order to convert it into a conductive film. The turning on and off of the power supply of the heater 15 is also controlled by the control unit 8.

In the droplet discharge apparatus 20 of the present embodiment, in order to discharge a dispersion solution onto a predetermined wire formation area, predetermined drive pulse signals are sent from the control unit 8 to the X direction drive motor 3 and/or the Y direction drive motor 6, so as to move the inkjet head group 1 and/or the mounting base 4. As a result, the inkjet head group 1 and the tape-shaped substrate 11 (i.e., the mounting base 4) are moved relatively to each other. During this relative movement, discharge voltage is supplied from the control unit 8 to predetermined inkjet heads 30 in the inkjet head group 1 so that dispersion solution is discharged from these inkjet heads 30.

In the droplet discharge apparatus 20 of the present embodiment, the quantity of droplets that are discharged from each inkjet head 30 of the inkjet head group 1 can be adjusted by changing the size of the discharge voltage that is supplied from the control unit 8. The pitch of the droplets that are discharged onto the tape-shaped substrate 11 is determined by the relative speed of movement of the inkjet head group 1 relative to the tape-shaped substrate 11 (i.e., to the mounting base 44), and by the discharge frequency (i.e, the frequency of the supply of discharge voltage) from the inkjet head group 1.

According to the droplet discharge apparatus 20 of the present embodiment, by moving the inkjet head group 1 along the X direction guide shaft 2 or the Y direction guide shaft 5, a pattern can be formed by causing droplets to land on optional positions in a desired area of the tape-shaped substrate 11. Namely, the droplet discharge apparatus 20 is able to form the partition wall 60 shown in FIG. 1A to 1D and is also able to form the flat, substantially uniform thin film 70. In addition, once the partition wall 60 and thin film 70 have been formed for one desired area, by then shifting the tape-shaped substrate 11 in the longitudinal direciton (i.e., in the Y direction), the partition wall 60 and thin film 70 can be formed extremely easily for other desired areas. Consequently, the present embodiment enables a pattern having a through hole to be formed with precision, and also easily and rapidly, in each desired area (i.e., in each circuit substrate area) of the tape-shaped substrate 11, and enables electronic circuits having multilayer wiring to be manufactured efficiently and in large quantity.

(Method Manufacturing a Multilayer Wiring Substrate)

Next, a description will be given of a method of manufacturing a multilayer wiring substrate using the pattern forming method of the above described embodiments. In the present embodiment, a description is given using as an example a method of manufacturing a multilayer wiring substrate, which has a wiring layer formed by a conductive film, an insulating layer, and a through hole, on a tape-shaped substrate 11 that forms a reel-to-reel substrate.

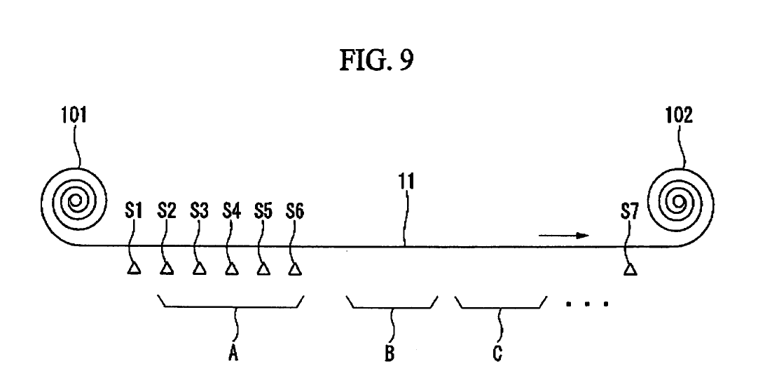

FIG. 9 is a typical view showing an outline of a method of manufacturing a multilayer wiring substrate according to the present embodiment. A system to which this manufacturing method is applied is formed so as to have at least a first reel 101 on which the tape-shaped substrate 11 is wound, a second reel 102 onto which the tape-shaped substrate 11 that has been pulled out from the first reel 101 is wound, and the droplet discharge apparatus 20 that discharges droplets onto the tape-shaped substrate 11.

A belt-shaped, flexible substrate, for example, may be used for the tape-shaped substrate 11, and polyimide or the like may be used for the base material thereof. Specifically, the tape-shaped substrate 11 may have a width of 105 mm and a length of 200 m. In addition, the two end portions of the belt shape of the tape-shaped substrate 11 are wound respectively onto the first reel 101 and the second reel 102 so as to form a “reel-to-reel substrate”. Namely, the tape-shaped substrate 11 that has been unwound from the first reel 101 is wound onto the second reel 102 such that it runs continuously in the longitudinal direction. The droplet discharge apparatus 20 discharges a liquid material in the form of droplets onto this continuously running tape-shaped substrate 11 so as to form a pattern (i.e., the partition wall 60 and the thin film 70).

This manufacturing method has a plurality of apparatuses that each execute a plurality of steps on the reel-to-reel substrate that is formed by a single tape-shaped substrate 11. Examples of the plurality of steps include a washing step S1, a surface processing step S2, a first droplet discharge step S3, a first curing step S4, a second droplet discharge step S5, a second curing step S7, and a baking step S7. By performing these steps a wiring layer and an insulating layer and the like can be formed on the tape-shaped substrate 11. It is assumed that a hole 50 (see FIG. 1A to 1D) has been formed in a desired position on the tape-shaped substrate 11.

In this manufacturing process, the tape-shaped substrate 11 is divided in the longitudinal direction into the desired lengths so that a large quantity of substrate formation areas (corresponding to the substrate 80) are set. The tap-shaped substrate 11 is then moved consecutively to the respect4ive apparatuses of each step, and wiring layers and insulating layers (for example, corresponding to the thin film 70) and the like are continuously formed on the respective substrate formation areas of the tape-shped substrate 11. Namely, the plurality of steps S1 to S7 are executed as a flow process, and this plurality of steps are each executed by the plurality of apparatuses either simultaneously or overlapping temporarally.

Next, the plurality of steps that are performed on the tape-shaped substrate 11, which is a reel-to-reel substrate, will be described specifically.

Firstly, a washing step S1 is executed on a predetermined area of the tape-shaped substrate 11 that has been unwound from the first reel 101 (step S1).

A specific example of the washing step S1 is the irradiation of ultraviolet (UV) light onto the tape-shaped substrate 11. The tape-shaped substrate 11 may also be washed by a solvent such as water, or may be washed using ultrasonic waves. The tape-shaped substrate 11 may also be washed by irradiating plasma thereon at normal pressure or in a vacuum.

Next, a surface processing step S2 is implemented in order to impart lyophilicity or repellency to a desired area of the tape-shaped substrate 11 where the washing step S1 has already been performed (step S2).

A specific example of the surface processing step S2 will now be described. In order to form wiring of a conductive film on the tape-shaped substrate 11 using a liquid material that contains fine conductive articles in the first droplet discharge step S3 of step S3, it is preferable to control the wettability of the surface of the desired area of the tape-shaped substrate 11 towards the liquid material that contains the fine conductive particles. A description of a surface processing method that enables a desired contact angle to be obtained is given below.

In the present embodiment, in order for a predetermined contact angle relative to a liquid material that contains fine conductive particles to be set to a desired value. two-stage surface processing is performed in which, firstly, liquid-repellency imparting process is performed on the surface of the tape-shaped substrate 11. Thereafter, liquid-affinity imparting process is performed in order to lessen the degree of repellency.

Firstly, a description will be given of a method to perform liquid-repellency imparting process on the surface of the tape-shaped substrate (i.e., the substrate) 11.

One method of performing liquid-repellency imparting process is a method in which a self-organized film that is formed by an organic molecular film or the like is formed on the surface of the substrate. The organic molecular film that is used to perform the processing of the substrate surface has a functional group that can be bonded to the substrate on one end side thereof, and has a functional group that modifies (i.e., controls the surface energy of, the surface of the substate to impart repellency or the like thereto on the other end side thereofe. In addition, the organic molecular film is provided with a carbon linear chain or with a partially split carbon chain that connects these functional groups. The organic molecular film is bonded to the substrate, and is self-organized so as to form a molecular film, for example, a monomolecular film.

A self-organized film is a film that is made up of a bonding functional group that is able to react with the constituent atoms of a base layer such as a substrate and with linear chain molecules other than these, and is formed by orienting a compound having extremely high orientability using the mutual interaction of the linear chain molecules. Because this self-organized film is formed by orienting mono molecules, the film thickness can be made extremely thin and, moreover, the film is uniform at the molecular level. Namely, because the same moleculesd are positioned on the film surface, the surface of the film is provided with uniform and excellent repellency.

If, for example, fluoroalkylsilane is used at the aforementioned compound having high orientability, then because the self-organized film is formed with each compound oriented such that the fluoroalkyl group is positioned on the surface of the film, uniform repellency is imparted to the surface of the film.

Examples of compounds that form a self-organized film include fluoralkylsilanes (abbreviated below to FAS) such as heptadecafluoro-1, 1, 2, 2 tetrahydrodecyltriethoxysilane, heptadecafluoro-1, 1, 2, 2 tetrahydrodecyltrimethoxysilane, heptadecafluoro-1, 1, 2, 2 tetrahydrodecyltrichlorosilane, tridecafluoro-1, 1, 2, 2 tetrahydrooctyltriethoxysilane, tridecafluoro-1, 1, 2, 2 tretrahydrooctyltrimethoxysilane, tridecafluoro-1, 1, 2, 2 tetrahydrooctyltrichlorosilane, and trifluoropropyltrimethoxysilane. At the time of use it is preferable that one compound is used individually, however, even if two or more compounds are used in combination, there is no restriction thereon, provided that the expected object of the present invention is not lost. Moreover, in the present embodiment, the above described FAS are used as the compound for forming the self-organized film, and they are used due to their adhesion with the substrate and to their ability to furnish excellent repellency.

FAS are generally expressed by the structural formula RnSiX₍₄₋ₐ₎. Here, n represents an integer of 1 or more and 3 or less, and X is a hydrolytic group such as a methodxy group, an ethoxy group, halogen atoms or the like. R is a fluoralkyl group and has a (CF₃) (CF₂) x (CH₂) y (here, x represents an inter of 1 or more and 10 or less, and y represents an integer of 0 or more and 4 or less) structure. If a plurality of R or X are bonded to Si, then the R or X may be all the same as each other or may be different from each other. The hydrolytic group represented by X forms silanol by hydrolysis and reacts with the hydroxyl group of a base such as the substrate (i.e., glass or silicon) so as to be bonded with the substrate by a siloxane bond. On the other hand, because R has a fluoro group such as (CF₃) on the surface thereof, it modifies a surface of a base such as a substrate or the like to a surface that does not become wet (i.e., that has low surface energy).

A self-organized film that is formed by an organic molecular film is formed on a substrate by leaving the above raw material compounds and the substrate in the same tightly sealed container for 2 to 3 days if the container is at room temperature. If the entire sealed container is kept at 100° C., then the self-organized film is formed on the substrate in approximately 3 hours. The above description is of a formation process from a vapor phase, however, a self-organized film can also be formed from a liquid phase.

For example, a self-organized film can be obtained on a substrate by immersing a substrate in a solution that contains the raw material compounds, and then washing it and drying it.

Note that, prior to the formation of the self-organized film, it is desirable that pre-processing is performed such as by irradiating ultraviolet light onto the substrate surface in the washing step S1 of step S1, or by washing the substrate surface in a solvent.

A method in which plasma is irradiated a room temperature can be given as an example of another method of performing liquid-repellency imparting process. The type of gas that is used for the plasma processing can be selected from a variety of types after consideration has been given to the surface properties and the like of the substfate. For example, a fluorocarbon based gas such as methane tetrafluoride, perfluorohexane, and perfluorodecane can be used as the processing gas. In this case, it is possible to form a repellent fluoride polymer film on the surface of the substrate.

The liquid-repellency imparting process can also be performed by adhering a film having the desired repellency, such as, for example, an ethylene tetrafluoride treated polyimide film or the like onto the substrate surface. Note that a polyimide film may also be used as it is as the tape-shaped substrate 11.

Next, a method of performing the liquid-affinity imparting process will be described.

Because a substrate surface at a stage where it has completed the above described liquid-repellency imparting process has a higher repellency thin that normally desired, the repellency can be tempered by liquid-affinity imparting process.

An example of the liquid-affinity imparting process is a method in which ultraviolet light of 170 to 400 nm is irradiated. By performing this process, the repellent film that has been formed is uniformly broken down either in portions or as a whole, resulting in the repellency being lessened.

In this case, the extent to which the repellency is lessened can be adjusted by the length of time of the ultraviolet light irradiation. It can also be adjusted by a combination of the time with the intensity, wavelength, and heat processing (i.e., heating) of the ultraviolet light.

Another method of performing the liquid-affinity imparting process is plasma processing using oxygen as the reaction gas. By performing this processing, the repellent film that has been formed is uniformly broken down either in portions or as a whole, resulting in the repellency being lessened.

A further method of performing the liquid-affinity imparting process is to expose the substrate to an ozone atmosphere. By performing this processing, the repellent film that has been formed is uniformly broken down either in portions or as a whole, resulting in the repellency being lessened. In this case, the extent to which the repellency is lessened can be adjusted by the irradiation output, the distance, and the time and the like.

Next, the first droplet discharge step S3 is performed, which is a wiring material coating step (step S3) in which a liquid material that contains fine, conductive particles is discharged and coated onto a predetermined area on the tape-shaped substrate 11 that has undergone the surface processing step S2.

The droplet discharge in the first droplet discharge step S3 is performed by the droplet discharge apparatus 20 shown in FIG. 6. If wiring is to be formed on the tape-shaped substrate 11, then the liquid material discharged in the first droplet discharge step is a liquid material that contains fine, conductive particles (i.e., pattern forming components). A dispersion solution obtained by dispersing fine, conductive particles in a dispersion medium is used as the liquid material that contains fine, conductive particles. The fine, conductive particles used here may be fine, metal particles containing any of gold, silver, copper, palladium or nickel, or else may be fine particles of a conductive polymer or a superconductor.

The fine, conductive particles may also be used after having the surface thereof coated with an organic substance or the like in order to improve their dispersion properties. Examples of the coating material that is coated on the surface of the fine, conductive particles include polymers that induce steric hindrance and electrostatic repulsion and the like. The particles diameter of the fine conductive particles is preferably 5 nm or more and 0.1 μm or less. If, the particle diameter is larger than 0.1 μm, nozzle blockages tend to occur, and discharges using an inkjet method become difficult. If the particle diameter is smaller than 5 nm, the volume ratio of the coating agent relative to the fine conductive particles increases and the proportion of organic matter in the resulting film is excessive.

It is preferable that the dispersion medium of the liquid material that contains the fine conductive particles has a vapor pressure at room temperature of 0.001 mmHg or more and 200 mmHg or less (i.e., approximately 0.133 Pa or more and 26600 Pa or less). If the vapor pressure is greater than 200 mmHg, the dispeersion medium abruptly evaporates after discharge and it becomes difficult to form an acceptable film.

It is more preferable that the vapor pressure of the dispersion medium is 0.001 mmHg or more and 50 mmHg or less (i.e., approximately 0.133 Pa or more and 6650 Pa or less). If the vapor pressure is greater than 50 mmHg, nozzle blockages tend to occur as a result of drying when droplets are discharged using an inkjet method (i.e., a droplet discharge method), and consistent discharging becomes difficult. On the other hand, if the dispersion medium is one whose vapor pressure at room temperature is lower than 0.001 mmHg, then the speed of the drying is slowed and dispersion medium tends to remain in the film. This makes it difficult to obtain a conductive film that maintains excellent qualities after the heat and/or light processing of the post-processing stage.

There is no particular restriction as to the dispersion medium that is used provided that it is able to disperse the above described fine conductive particles and does not cause flocculation. Examples thereof, in addition to water, include: alcohols such as methanol, ethanol, propanol, and butanol; hydrocarbon based compounds such as n-heptaine, n-octane, decane, toluene, xylene, cymene, dulene, indene, dipentene, tetrahydronaphthalene, decahydronaphthalene, and cyclohexylbenzene; or ether base compounds such as ethylene glycol dimethyl ether, ethylene glycol diethyl ether, ethylene glycol methylethyl ether, diethylene glycol dimethyl ether, diethylene glycol diethyl ether, diethylene glycol methylethyl ether, 1,2-dimethoxyethane, bis (2-methoxyethyl) ether, and p-dioxane. In addition, polar compounds such as propylene carbonate, γ-butyrolactone, N-methyl-2-pyrrolidone, dimethyl formamide, dimethyl sulfoxide, and cyclohexanone. Among these, due to the dispersibility of the fine particles and to the stability of the dispersion solution, and due also to the ease with which they can be used in an inkjet process, water, alcohols, hydrocarbon based compounds, and ether based compounds are preferable, with water and hydrocarbon based compounds being more preferable for the dispersion solution. These dispersion mediums may be used singly or may be used in combinations of two or more.

The dispersoid concentration when the above described fine conductive particles are dispersed in the dispersion medium is 1 mass percent or more and 80 mass percent or less, and can be adjusted in accordance with the film thickness that is desired for the conductive film. If the dispersoid concentration exceeds 80 mass percent, then flocculation tends to occur and it is difficult to obtain a uniform film.

It is preferable that the surface tension of the dispersion solution of the above described fine conductive particles is within a range of 0.02 N/m or more and 0.07 N/m or less. When a liquid material is discharged using an inkjet method, if the surface tension is less than 0.02 N/m, filled the wettability of the ink composition of matter relative to the nozzle surface increases so that spattering tends to occur. If the surface tension exceeds 0.07 N/m, then because the configuration of the meniscus at the distal end of the nozzle is not stable, control of the discharge quantity and discharge timing becomes difficult.

In order to adjust the surface tension, it is possible to add minute quantities of surface tension adjusting agents such as fluorine based agents, silicon based agents, and nonion based agents to the above described dispersion solution within a range whereby the contact angle with the substrate is not excessively reduced. Nonion based surace tension adjusting agents serve to improve the wettability of the liquid material to the substrate, to improve the leveling off the film, and to prevent the occurrence of irregularities in the coating film, or so-called organe peel surface. It is also possible for the above described dispersion solution to contain, if necessary, an organic compound such as alcohol, ether, ester, ketone, and the like.

The viscosity of the above described dispersion solution is preferably 1 mPa·s or more and 50 mPa·s or less.

When discharging using an inkjet method, if the viscosity is smaller than 1 mPa·s, then the nozzle peripheral portions tend to become contaminated by ink outflow. If the viscosity is larger than 50 mPa·s, then the frequeny at which blockages occur in the nozzle holes increases, and it becomes difficult to perform a smooth droplet discharge.

In the present embodiment, droplets of the above described dispersion solution are discharged from an inkjet head and dropped onto locations where wiring is to be formed on a substrate. At this time, it is necessary to control the extent to which consecutively discharged droplets overlap in order that bulges are not generated. It is also possible to employ a discharge method in which, in a first discharge, a plurality of droplets are separated so as not to come into contact with each other, and these gaps are then filled in by a second and subsequent discharges.

Next, a first curing step (step S4) is performed on desired areas of the tape-shaped substrate 11 that has undergone the first droplet discharge step S3.

The first curing step is a wiring curing step in which a liquid material that contains the conductive material that has been coated onto the tape-shaped substrate 11 in the first droplet discharge step S3 is cured. By repeatedly performing the above described step S3 and step S4 (and including step S2 if so desired), the film thickness can be increased, and wiring and the like having the desired configuration and the desired film thickness can be easily formed.

Specifically, the first curing step S4 can be performed using, for example, processing to heat the tape-shaped substrate 11 using a normal hot plate or electric furnace, as well as by lamp annealing. There are no particular restrictions as to the light source of the light that is used for this lamp annealing, and an infrared lamp, a xenon lamp, a YAG laser, an argon laser, a carbon dioxide gas laser, and excimer lasers such as XeF, XeCl, XeBr, KrF, KrCl, ArF, ArCl, and the like can be used as the light source. These light sources typically have an output in a range from 10 W or more to 5000 W or less, however, in the present embodiment, a range of between 100 W or more and 1000 W or less is sufficient.

Next, the second droplet discharge step S5 (step S5), which is an insulating material coating step, is performed on a predetermined area of the tape-shaped substrate 11 that has undergone the first curing step S4.

The droplet discharge in this second droplet discharge step S5 is also performed using the droplet discharge apparatus 20 shown in FIG. 6. However, it is preferable that the droplet discharge apparatus 20 used in the first droplet discharge step S3 is a separate apparatus from the droplet discharge apparatus 20 used in the second droplet discharge step S5. By employing separate apparatuses, the first droplet discharge step S3 and the second droplet discharge step S5 can be performed simultaneously, and it is possible to achieve an improvement in the manufacturing speed as well as an improvement in the operating ratio of the droplet discharge apparatuses.

The second droplet discharge step S5 is a step in which an insulating liquid material is coated by a droplet discharge apparatus onto a top layer of the wiring layer of the tape-shaped substrate 11 that has completed the first droplet discharge step S3 and the first curing step S4. Namely, in the second droplet discharge step S5, as is shown in FIG. 1A to 1D, firstly, the partition wall 60 is formed around the hole 50. Next, a flat, substantially uniform insulating thin film 70 is formed over the entire pattern formation area. As a result, a through hole that penetrates an insulating layer formed by the thin film 70 can be formed accurately. By performing this step, the wiring pattern that was formed by the first droplet discharge step S3 and the first curing step S4 is covered by an insulating film. It is preferable that, prior to this second droplet discharge step S5 being performed, surface processing corresponding to the above described surface processing step S2 of step S2 is performed. Namely, it is preferable that liquid-affinity imparting process is performed on an entire predetermined area of the tape-shaped substrate 11.

Next, the second curing step S6 (step S6) is performed on a predetermined area of the tape-shaped substrate 11 that has undergone the second droplet discharge step S5.

The second curing step S6 is an insulating material curing step in which the insulating liquid material that was coated on the tape-shaped substrate 11 in the second droplet discharge step S5 is cured. By repeatedly performing the above described step S5 and step S6 (and including a surface processing step if so desired), the film thickness can be increased, and an insulating layer and the like having the desired configuration and the desired film thickness can be easily formed. The specific example of the first curing step S4, which is given above, can also be applied to the second curing step S6.

The above described steps S2 to S6 make up a first wiring layer formation step A that forms a first wiring layer. After this first wiring layer formation step A, by then further performing the above described steps S2 to S6, it is possible to form a second wiring layer that is provided with a through hole on a top layer of the first wiring layer. The steps to form this second wiring layer constitute a second wiring layer formation step B. After this second wiring layer formation step B, by then further performing the above described steps S2 to S6, it is possible to form a third wiring layer that is provided with a through hole on a top layer of the second wiring layer. The steps to form this third wiring layer constitute a second wiring layer formation step C. In this manner, by repeating the above described steps S2 to S6, it is possible to easily form excellent multilayer wiring that is provided with a through hole.

Next, after the first wiring layer, the second wiring layer, and the third wiring layer have been formed using the above described steps S2 to S6, a baking step S7 (step S7) is performed in which a predetermined area of the tape-shaped substrate 11 is baked.

This baking step S7 is a step in which a wiring layer that was coated in the first droplet discharge step S3 and thereafter dried, and an insulating layer that was coated in the second droplet discharge step S5 and thereafter dried are baked together. By performing the baking step S7, electrical contact is secured between the fine particles in the wiring patern on the wiring layer of the tape-shaped substrate 11, and this wiring pattern is converted into a conductive film. In addition, by performing the baking step 87, the insulating properties of the insulating layer of the tape-shaped substrate 11 are improved.

The baking step S7 is performed in a normal atmosphere, however, if necessary, it can also be performed in an inert gas atmosphere of nitrogen, argon, helium, or the like. The processing temperature of the baking step S7 can be appropriately determined after considering the boiling point (i.e., the vapor pressure) of the dispersion medium that is contained in the liquid material that is coated in the first droplet discharge step S3 and the second droplet discharge step S5, the type and pressure of the unit gas, the thermal behavior of the fine particles such as their dispersibility and oxidizability, the existence or otherwise as well as the quantity of the coating material, and the heat resistant temperature of the substrate. For example, a predetermined area of the tape-shaped substrate 11 may be baked at 150° C. in the baking step S7.

This type of baking processing can be performed by lamp annealing in addition to by using a normal hotplate, electrical furnace, or the like. There are no particular restrictions as to the light source of the light that is used for this lamp annealing, and an infrared lamp, a xenon lamp, a YAG laser, an argon laser, a carbon dioxide gas laser, and excimer lasers such as XeF, XeCl, XeBr, KrF, KrCl, ArF, ArCl, and the like can be used as the light source. These light sources typically have an output in a range from 10 W or more to 5000 W or less, however, in the present embodiment, a range of between 100 W or more and 1000 W or less is sufficient.

According to the present embodiment, by performing these steps, because multilayer wiring having a through hole is formed on a tape-shaped substrate 11, which is a reel-to-reel substrate, using a droplet discharge method, it is possible to manufacture efficiently and in a large quantity highly precise, compact electronic circuit substrates and the like. Namely, according to the present embodiment, by aligning a desired area of a single tape-shaped substrate 11, which is to be formed into a large number of plate shaped substrates during production, with a predetermined position of the droplet discharge apparatus 20, it is possible to form a desired wiring pattern on that desired area. Therefore, after pattern formation has been completed on a single desired area using the droplet discharge apparatus 20, by shifting the tape-shaped substrate 11 relative to the droplet discharge apparatus, it is possible to form a wiring pattern on other desired areas of the tape-shaped substrate 11 extremely easily. Consequently, the present embodiment enables a precise wiring pattern to be formed easily and rapidly on each desired area of the tape-shaped substrate 11, which is a reel-to-reel substrate. The present embodiment also enables wiring substrates and the like to be formed with precision, efficiently, and in large quantities.

Moreover, according to the present embodiment, a plurality of steps including droplet coating steps are executed between the time when the tape-shaped substrate 11, which is a reel-to-reel substrate, is unwound from the first reel 101 and the time when it is wound onto the second reel 102. As a result, the tape-shaped substrate 11 can be moved simply by winding one end side of the tape-shaped substrate 11 using the second reel 102 from the apparatus that executes the washing step S1 to the apparatus that executes the subsequent surface processing step S2, and then again to the apparatuses that execute the subsequent steps. Accordingly, according to the present embodiment, the transporting mechanism and the alignment mechanism that transport the tape-shaped substrate 11 to each apparatus of each step can be simplified, thereby enabling the space required to install the manufacturing apparatuses to be reduced, and enabling manufacturing costs for large-scale production to be reduced.

Moreover, in the pattern forming system and pattern forming method of the present embodiment, it is preferable that the time required to perform each step of the plurality of steps is substantially identical. If such a system is employed, each step can be executed in parallel simultaneously. This enables more rapid manufacturing to be achieved, and enables the utilization efficiency of each apparatus of each step to be improved. Here, in order to make the time required for each step the same, the number or capabilities of the apparatuses (for example, the droplet discharge apparatus 20) used in each step may be adjusted. For example, if the time required for the second droplet discharge step S5 is longer than the time required for the first droplet discharge step S3, then one droplet discharge apparatus 20 can be used in the first droplet discharge step S3, and two droplet discharge apparatuses 20 can be used in the second droplet discharge step S5.

(Electronic Apparatus)

Next, a description will be given of an electronic apparatus manufactured using the pattern forming method of the above described embodiments.

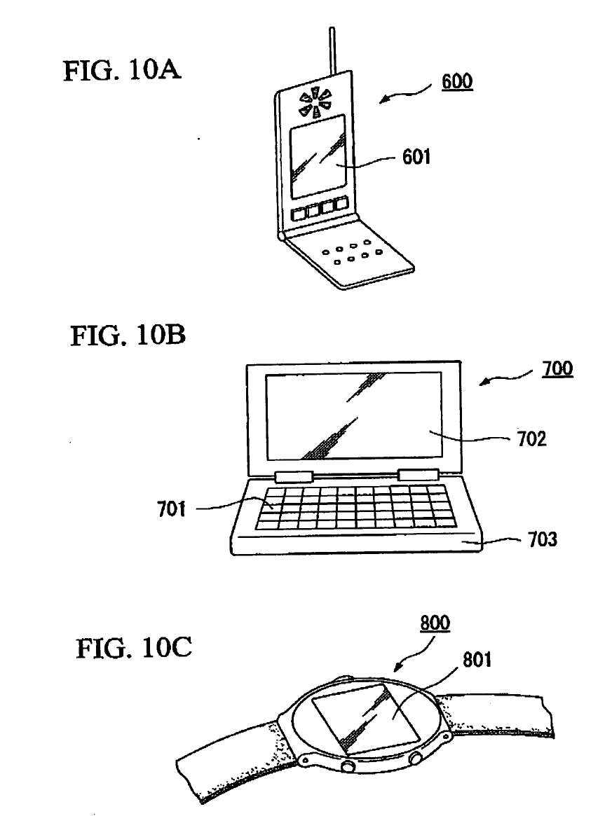

FIG. 10A is a perspective view showing an example of a mobile telephone. In FIG. 10A, the symbol 600 indicates a mobile telephone in which multilayer wiring has been formed using the pattern forming method of the above described embodiments, and the symbol 601 indicates a display section formed by an electro-optical device. FIG. 10B is a perspective view showing an example of a portable type of information processing apparatus such as a word processor or personal computer. In FIG. 10B, the symbol 700 indicates an information processing device, the symbol 701 indicates an input device such as a keyboard, the symbol 702 indicates a display section formed by an electro-optical device, and the symbol 703 indicates an information processing device body in which multilayer wiring has been formed using the pattern forming method of the above described embodiments. FIG. 10C is a perspective view showing an example of a wristwatch type of electronic apparatus. In FIG. 10C, the symbol 800 indicates an wristwatch body in which multilayer wiring has been formed using the pattern forming method of the above described embodiments, and the symbol 801 indicates a display seciton formed by an electro-optical device.

Because the electronic apparatuses shown in FIG. 10A to 10C are provided with multilayer wiring that has been formed using the pattern forming method of the above described embodiments, they can be manufactured at low cost, with a high level of product quality, and in large quantity.

It should be understood that the technological range of the present invention is not limited by the above described embodiments. Various modifications can be made without departing from the spirit or scope of the present invention. Accordingly, the specific materials and layer structures and the like described in the above embodiment are only examples thereof, and may be modified as is appropriate. For example, in the above described embodiments, a description is given of a pattern forming method that is used in the manufacture of multilayer wiring, however, the present invention is not limited to this and it can also be applied to the manufacturing of a variety of electro-optical apparatuses such as various integrated circuits or organic EL apparatuses, plasma display apparatuses, and liquid crystal display apparatuses, or to the manufacturing of color filters and the like. Namely, a thin film pattern formed using the pattern forming method of the present invention is not limited to a wiring pattern, and pixels, electrodes, and various types of semiconductor elements can also be formed using the pattern forming method of the present invention.

1. A pattern forming method comprising the step of forming a partition wall, at least a portion of a boundary between a pattern formation area and other areas, by coating droplets using a droplet discharge method.

2. A pattern forming method according to claim 1,
wherein the partition wall is formed in a linear configuration by:
performing a first coating in which a plurality of droplets are coated onto at least a portion of the boundary with a space between each droplet using a droplet discharge method; and
performing a second coating in which, after the first coating, droplets are coated onto the spaces using the droplet discharge method.

3. A pattern forming method according to claim 2, wherein the second coating is performed after at least surfaces of the droplets coated in the first coating have cured.

4. A pattern forming method according to claim 2, wheerein the droplets coated in the first coating and the droplets coated in the second coating have overlapping portions.

5. A pattern forming method according to claim 1, wherein a thin film is formed in the pattern formation area.

6. A pattern forming method according to claim 5, wherein the thin film is formed in flat and substantially uniform, after at least surfaces of the droplets that constitute the partition wall have cured.

7. A pattern forming method according to claim 1, wherein the boundary is a boundary region between a through hole provided in a pattern formation surface that includes the pattern formation area, and the pattern formation surface.

8. A pattern forming method according to claim 1,
wherein the pattern formation area has corner portions, and
at least a portion of the boundary is the corner portion.

9. A pattern forming method according to claim 1, wherein, prior to the partition wall being provided, liquid-repellency imparting process or liquid-affinity imparting process is performed on an area that includes a location where the partition wall is provided.

10. A pattern forming method according to claim 1, wherein, prior to the partition wall being provided, liquid-repellency imparting process is performed on a location where the partition wall is provided and to the vicinity of the location.

11. A pattern forming method acording to claim 5, wherein, prior to the thin film being formed on the pattern formation area, liquid-affinity imparting process or liquid-repellency imparting process is performed on the pattern formation area.

12. A pattern forming method according to claim 5, wherein, prior to a thin film being formed on the pattern formation area, liquid-affinity imparting process is performed on areas other than the vicinity of the boundary in the pattern formation area.

13. A pattern forming method according to claim 1, wherein the pattern formation area is provided on a substrate that is formed by a tape-shaped substrate, and both end portions of the tape-shaped substrate are each wound up.

14. A circuit substrate comprising a pattern that has been formed using the pattern forming method according to claim 1.

15. An electronic apparatus that has been manufactured using the pattern forming method according to claim 1.
